(19) United States
(12) Patent Application Publication
(10) Pub. No.: US 2013/0020689 A1
(43) Pub. Date: Jan. 24, 2013

(54) SEMICONDUCTOR DEVICE AND METHOD OF PACKAGING SAME

(71) Applicants: Penglin Mei, Tianjin (CN); Liwei Liu, Tianjin (CN); Dehong Ye, Tianjin (CN)

(72) Inventors: Penglin Mei, Tianjin (CN); Liwei Liu, Tianjin (CN); Dehong Ye, Tianjin (CN)

(73) Assignee: FREESCALE SEMICONDUCTOR, INC, Austin, TX (US)

(21) Appl. No.: 13/489,471

(22) Filed: Jun. 6, 2012

(30) Foreign Application Priority Data
Jul. 18, 2011 (CN) 201110228863.0

(51) Int. Cl. H01L 21/60; H01L 23/495

(52) U.S. Cl. 257/676; 438/118; 438/123; 257/E21.51; 257/E23.033

(57) ABSTRACT

A Quad Flat Pack (QFP) device includes a semiconductor die attached to a flag of a lead frame. Bonding pads of the die are electrically connected to inner and outer rows of leads of the lead frame with bond wires. The die, die flag, bond wires and portions of the inner and outer leads are covered with a mold compound, which defines a package body. The outer leads are similar to the gull-wing leads of a conventional QFP device while the inner leads form contact points at a bottom surface of the package body. A cut is performed on an inner side of the inner leads to separate the inner leads from the die pad.

### BACKGROUND OF THE INVENTION

The present invention relates generally to packaging of semiconductor devices, and more particularly to a method of assembling quad flat package (QFP) semiconductor devices.

Semiconductor integrated circuits are continually decreasing in size and there is a corresponding demand for such smaller yet denser circuits. At the same time, there is a desire for such circuits to provide the same or more inputs and outputs (I/Os), which is quite a challenge for packaging engineers. Some types of semiconductor packages use lead frames that have leads or lead fingers that are used to interconnect the semiconductor die with external electrical circuitry. Typically, contacts or pads on the semiconductor die are electrically coupled to respective leads or lead fingers with bond wires.

FIG. 1 shows a cross-sectional view of a conventional quad flat pack (QFP) 10 having a semiconductor die 12. The die 12 is attached to and supported by a die pad 14 of a lead frame 16. The die 12 also is electrically connected to leads 18 of the lead frame 16 with bond wires 20. The die 12, bond wires 20, and parts of the leads 18 are covered with an encapsulation material 22 such as an epoxy resin. The QFP 10 is generally square shaped and the leads 18 extend outwardly from the encapsulation material 22 along the four peripheral sides. Typically the leads 18 are bent so that a distal end of the leads 18 is below or at least on the same plane as a bottom surface of the QFP 10. This bent shape is known as a gull-wing shape.

Since there is a minimum spacing required between adjacent leads so that the leads don't short circuit and since package size is decreasing, it would be advantageous to be able to provide a package design that allows for the same or an increased number of leads.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 is a cross-sectional view of a conventional quad flat pack (QFP) package;

FIG. 2 is a cross-sectional view of a semiconductor package in accordance with one embodiment of the present invention;

FIG. 3 is a bottom plan view of the semiconductor package of FIG. 2; and

FIG. 4 is a bottom plan view of the semiconductor package of FIG. 2 with the inner leads separated from the die flag.

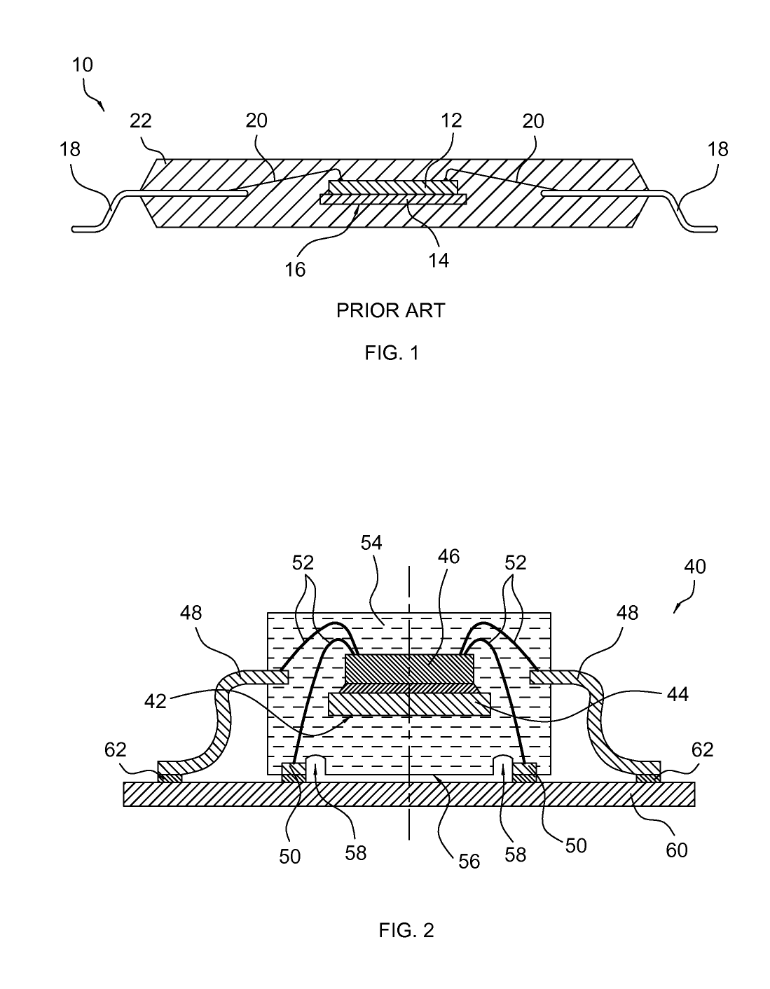

### DETAILED DESCRIPTION OF THE INVENTION

Detailed illustrative embodiments of the present invention are disclosed herein. However, specific structural and functional details disclosed herein are merely representative for purposes of describing example embodiments of the present invention. The present invention may be embodied in many alternate forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “includes,” and/or “including,” specify the presence of stated features, steps, or components, but do not preclude the presence or addition of one or more other features, steps, or components. It also should be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment, the present invention provides a method of assembling a semiconductor device. The method includes providing a lead frame having a die flag surrounded by an inner row of leads and an outer row of leads. The outer row leads are attached to an outer frame member and the inner row leads are attached to the die flag. A semiconductor die is attached to the die flag and then bond pads of the die are electrically connected to the leads of the inner and outer rows of leads. The die flag, die, and electrical connections between the bond pads and the leads of the inner and outer rows of leads are encapsulated with a molding compound. The inner row leads are separated from the die flag and the outer row leads are separated from the outer frame member. The molding compound forms a package body with the inner row leads extending from a bottom surface of the package body and the outer row leads extend from side surfaces of the package body. The outer row leads a like a typical QFP gull-wing lead while the inner row leads form an additional row of leads.

In another embodiment, the present invention is a semiconductor device packaged in accordance with the above-described method.

Referring now to FIG. 2, a cross-sectional view of a semiconductor device 40 is shown. The semiconductor device 40 includes a lead frame 42 with a die flag 44. The lead frame 42 may be formed of a metal or a metal alloy. In certain exemplary embodiments, the lead frame 12 may be formed of copper, copper alloys, iron, aluminium, aluminium alloys, steel or other appropriate materials. The lead frame also may be coated with another metal material such as palladium. Lead frames are well known to those of skill in the art who will understand that the lead frame of the present invention may comprise a wide variety of materials and may be formed in a wide variety of manners such as cutting, stamping and etching.

A semiconductor die 46 is attached to the die flag 44. The semiconductor die 46 may comprise any type of functional circuit such as a processor, control circuit, system on a chip (SoC), memory (e.g., DRAM), etc. and the present invention should not be limited to any particular semiconductor die. The present invention also should not be limited by the material or fabrication method of the die itself or technology type of the die, such as whether the die is formed from Silicon, Gallium Arsenide, or another material. The semiconductor die 46 may be attached to the die flag 44 using a die attach adhesive as are known to those of skill in the art and typically used in semiconductor device assembly. The die attach adhesive is dispensed onto the top surface of the die flag 44 using a known dispensing device and the semiconductor die 46 is placed on the die attach adhesive. The adhesive then preferably is oven cured to allow for the formation of a strong bond between the die 46 and the die flag 44.

The semiconductor device includes an outer row of leads 48 that surround the die flag 44 and protrude and extend from sides of the device 40. The semiconductor device 40 also includes an inner row of leads 50 that surround the die flag 44 and are disposed between the outer row of leads 48 and the die flag 44. As can be seen in FIG. 2, the inner row leads 50 are located at a bottom surface of the semiconductor device 40.

In the illustrated embodiment, the outer row leads 48 and the inner row leads 50 are electrically coupled to bond pads of the semiconductor die 46 with bond wires 52. The bond wires 52 are connected to the die bonding pads and the outer and inner rows leads 48, 50 using well known wire bonding processes and equipment. The bond wires 52 are formed from a conductive material such as aluminum, copper and gold and may be bare or coated with another metal such as palladium.

A molding compound 54 is used to encapsulate the die flag 44, die 46, bond wires 52 and portions of the outer and inner rows leads 48, 50. The molding compound 54 forms a package body and as previously discussed, the outer row leads 48 extend or protrude from sides of the package body and the inner row leads 50 are exposed at a bottom surface 56 of the package body. The molding compound 54 may include plastic or an epoxy molding compound, as is known in the art.

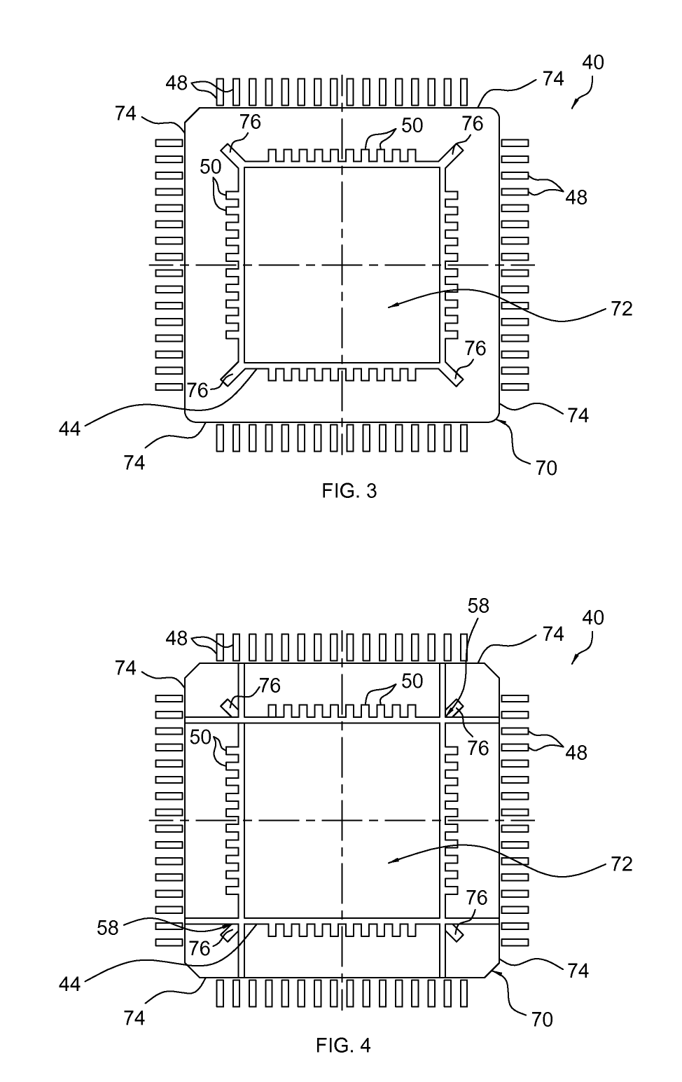

In one embodiment of the invention, the inner row leads 50 are part of or connected to the die flag 44 but then are separated from the die flag 44 such as with a saw. In a preferred embodiment of the invention, the half-cut with a saw is performed to separate the inner row leads 50 from the die flag 44, which leaves a channel 58 in a bottom surface 56 of the device 40 along inner edges of the inner row leads 50. On the other hand, as will be discussed in more detail below, the outer row leads 48 are attached to an outer frame member (FIGS. 3 and 4) of the lead frame 42, which is cut away during the assembly process. It should be noted that the molding compound body 54 covers the die flag 44 so in this embodiment, the die flag 44 is not exposed.

The outer row leads 48 also may be bent to a full wing shape. In the embodiment shown, the outer row leads 48 have a proximal portion that protrudes from a side of the molding compound 54 and a distal portion that, after bending, lies in a same plane as the inner row leads 50 so that the device 40 may be easily attached to a printed circuit board (PCB) 60. Also as will be noted by those of skill in the art, the semiconductor device 40 has a quad flat pack (QFP) configuration. Another embodiment of the invention is a low-profile quad flat package (LQFP).

FIG. 3 is a bottom plan view of the semiconductor device 40 of FIG. 2. As illustrated, the semiconductor device 40 includes the lead frame 42, which has an outer frame member 70 that defines an opening 72. The outer frame 70 has a generally rectangular, or in the embodiment shown, square shape with four peripheral edges 74 of substantially equal length.

The die pad 44 of the lead frame 42 is disposed within the opening 72 and also has a generally square shape. As will be appreciated by those skilled in the art, the die pad 44 may be shaped as necessary to receive a die such as the die 46 and similarly, the outer frame 70 may also have alternative shapes. The die pad 44 is supported within the opening 72 by tie bars 76 located at the corners of the die pad 44. The tie bars 76 are connected to and extend between the outer frame 70 and respective ones of the four corners of the die pad 44.

In this exemplary embodiment, the outer row leads 48 are integral with and extend, in this instance outwardly, from the peripheral edges 74 of the outer frame member 70. On the other hand, the inner row leads 50 are integral with the die pad 44. It should be noted that the number of the outer and inner rows of leads 48 and 50 in FIG. 3 is for illustrative purposes, and each side may have more or fewer leads that extend therefrom.

FIG. 4 is a bottom plan view of the semiconductor package 40 of FIG. 2 with the inner leads 50 separated from the die flag 44. In one embodiment of the invention, a saw blade is employed for cut into the molding compound 54 to form half cuts 58 that electrically isolate the inner leads 50 from the die flag 44. The molding compound 54 is cut by the saw blade to a depth sufficient to effectively separate and electrically isolate each of the inner leads 50 from the die flag 44 but not so much as to damage the wires 52 extending between the die bonding pads and the inner row leads 50.

By having the inner row leads, the present invention provides a semiconductor package with increased input/output (I/O) leads without requiring an increase in package size. Further, the present invention employs well known and well developed technologies such as lead frame and wire bonding. The techniques described above may be used to form QFP and LQFP packages.

The package design includes inner leads on the bottom of the package and outer leads that extend from the package body. The package body is formed using a molding compound to cover the semiconductor die and portions of the outer and inner leads. In the embodiment shown, the die pad 44 is not exposed although in some embodiments it may be.

By now it should be appreciated that there has been provided an improved quad flat package and a method of forming the quad flat package. Circuit details are not disclosed because knowledge thereof is not required for a complete understanding of the invention. Although the invention has been described using relative terms such as “front,” “back,” “top,” “bottom,” “over,” “under” and the like in the description and in the claims, such terms are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

1. A method of assembling a semiconductor device, comprising the steps of:
providing a lead frame having a die flag surrounded by an inner row of leads and an outer row of leads, wherein the outer row leads are attached to an outer frame member and the inner row leads are attached to the die flag;
attaching a semiconductor die to the die flag;
electrically connecting bond pads of the semiconductor die to the leads of the inner and outer rows of leads;
encapsulating the die flag, die, and electrical connections between the bond pads and the leads of the inner and outer rows of leads with a molding compound;
separating the inner row leads from the die flag; and
separating the outer row leads from the outer frame member, whereby the molding compound forms a package body, the inner row leads extend from a bottom surface of the package body and the outer row leads extend from side surfaces of the package body.

2. The method of assembling a semiconductor device of claim 1, wherein separating the inner row leads from the die flag comprises sawing the package body to form half cuts that electrically isolate the inner leads from the die flag.

3. The method of assembling a semiconductor device of claim 1, wherein the electrically connecting step comprises connecting the bond pads of the semiconductor die to the leads of the inner and outer rows of leads with bond wires using a wire bonding process.

4. The method of assembling a semiconductor device of claim 1, comprising forming the package body such that a bottom surface of the die flag is covered with the molding compound.

5. The method of assembling a semiconductor device of claim 1, wherein the outer row leads are bent to form a gull-wing configuration.

6. The method of assembling a semiconductor device of claim 5, wherein distal ends of the outer row leads lie in a same plane as a bottom surface of the package body.

7. The method of assembling a semiconductor device of claim 6, wherein the die flag is in a plane that is spaced from the plane of the bottom surface of the package body.

8. The method of assembling a semiconductor device of claim 1, wherein attaching the semiconductor die comprises attaching the semiconductor die to the die flag using an adhesive and curing the adhesive.

9. The method of assembling a semiconductor device of claim 8, wherein the adhesive comprises at least one of epoxy and solder.

10. A semiconductor device formed in accordance with the method of claim 1.

11. A semiconductor device, comprising:
a lead frame having a die flag surrounded by an inner row of leads and an outer row of leads, wherein the outer row leads are attached to an outer frame member and the inner row leads are attached to the die flag;
a semiconductor die attached to the die flag;
electrical connections between bonding pads on an active surface of the semiconductor die and the leads of the inner and outer rows of leads; and
an encapsulation material formed around the semiconductor die, the die flag, the electrical connections, and portions of the leads of the inner and outer rows of leads, wherein the encapsulation material forms a package body and the outer row leads extend outwardly from side surfaces of the package body and the inner row leads are exposed on a bottom surface of the package body, and wherein the outer row leads have been separated from the outer frame member and the inner row leads have been separated from the die flag.

12. The semiconductor device of claim 11, wherein the electrical connections comprise bond wires.

13. The semiconductor device of claim 12, wherein the bond wires are formed of gold.

14. The semiconductor device of claim 11, wherein the encapsulation material comprises epoxy.

15. The semiconductor device of claim 11, wherein a bottom surface of the die pad is covered with the encapsulation material.

16. The semiconductor device of claim 11, wherein the semiconductor device comprises one of a quad flat package (QFP) and a low-profile quad flat package (LQFP).

17. A method of assembling a semiconductor device, comprising the steps of:
providing a lead frame having a die flag surrounded by an inner row of leads and an outer row of leads, wherein the outer row leads are attached to an outer frame member and the inner row leads are attached to the die flag;
attaching a semiconductor die to the die flag with an adhesive;
electrically connecting bond pads of the semiconductor die to the leads of the inner and outer rows of leads with bond wires;
encapsulating the die flag, die, and electrical connections between the bond pads and the leads of the inner and outer rows of leads with a molding compound, wherein the molding compound forms a package body;
separating the inner row leads from the die flag with a half-cut; and
separating the outer row leads form the outer frame member, wherein the inner row leads extend from a bottom surface of the package body and the outer row leads extend from side surfaces of the package body.

18. The method of assembling a semiconductor device of claim 17, wherein the semiconductor die is attached to a top surface of the die flag and a bottom surface of the die flag is covered with the molding compound.

19. The method of assembling a semiconductor device of claim 17, wherein the outer leads protrude from side surfaces of the package body, and portions of the inner leads extend from a bottom surface of the package body.

20. The method of assembling a semiconductor device of claim 19, wherein the outer leads are bent to a gull-wing shape.
